(19) United States
(12) Patent Application Publication
(10) Pub. No.: US 2026/0211194 A1
(43) Pub. Date: Jul. 23, 2026

(54) OPTICAL DEVICES AND METHODS OF FORMING THE SAME

(71) Applicant: Taiwan Semiconductor Manufacturing Co., Ltd., Hsinchu (TW)

(72) Inventors: Chia-Han Tsou, Hsinchu (TW); Ming-Fa Chen, Taichung (TW)

(21) Appl. No.: 19/201,011

(22) Filed: May 7, 2025

Related U.S. Application Data
(60) Provisional application No. 63/748,765, filed on Jan. 23, 2025.

(51) Int. Cl. G02B 6/42; G02B 6/43; H01L 25/00; H01L 25/16

(52) U.S. Cl. CPC G02B 6/4215; G02B 6/43; H10W 90/00

(57) ABSTRACT

A method includes forming a photonic integrated circuit including: a first waveguide; a second waveguide over the first waveguide, wherein the second waveguide is optically coupled to the first waveguide; a first external coupler that is optically coupled to the second waveguide; and a first interconnect structure; attaching an electronic die to a first side of the photonic integrated circuit; direct bonding a first photonic die to a second side of the photonic integrated circuit, wherein the first photonic die is optically coupled to the first waveguide after the direct bonding; and forming a second interconnect structure over the first photonic die and the photonic integrated circuit.

### PRIORITY CLAIM AND CROSS-REFERENCE

This application claims the benefit of U.S. Provisional Application No. 63/748,765, filed on Jan. 23, 2025, which application is hereby incorporated herein by reference.

### BACKGROUND

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) components and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, and 10 illustrate intermediate steps in the formation of an optical engine having a photodetector die, in accordance with some embodiments.

FIG. 11 illustrates an optical engine having a photodetector die, in accordance with some embodiments.

FIG. 12 illustrates an optical engine having a photodetector die, in accordance with some embodiments.

FIG. 13 illustrates an optical engine having a photodetector die, in accordance with some embodiments.

FIG. 14 illustrates an optical engine having a photodetector die, in accordance with some embodiments.

FIGS. 15 and 16 illustrate intermediate steps in the formation of an optical engine having a modulator die, in accordance with some embodiments.

FIG. 17 illustrates an optical engine having a modulator die, in accordance with some embodiments.

FIG. 18 illustrates an optical engine having a modulator die, in accordance with some embodiments.

FIG. 19 illustrates an optical engine having a modulator die, in accordance with some embodiments.

FIG. 20 illustrates an optical engine having a modulator die and a photodetector die, in accordance with some embodiments.

FIG. 21 illustrates a top-down view of an optical engine, in accordance with some embodiments.

FIG. 22 illustrates an optical engine having a modulator die and a photodetector die, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various structures such as packages comprising photonic structures, optical engines, or the like and their methods of formation are described herein. During formation of an optical engine, a photonic die, such as a photodetector die and/or a modulator die, is directly bonded to a photonic integrated circuit (PIC). This can allow for more efficient or higher-bandwidth photodetectors or modulators to be used within the optical engine. The photonic die can be optically coupled to waveguides within the optical engine. In this manner, the data rate of the optical engine may be improved.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order. The embodiments presented herein are intended to be illustrative and are not intended to limit the embodiments to the precise descriptions as discussed. Rather, the embodiments discussed may be incorporated into a wide variety of implementations, and all such implementations are fully intended to be included within the scope of the embodiments.

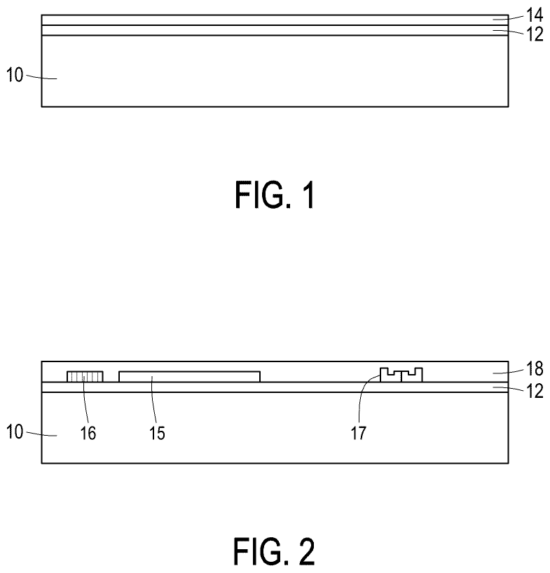

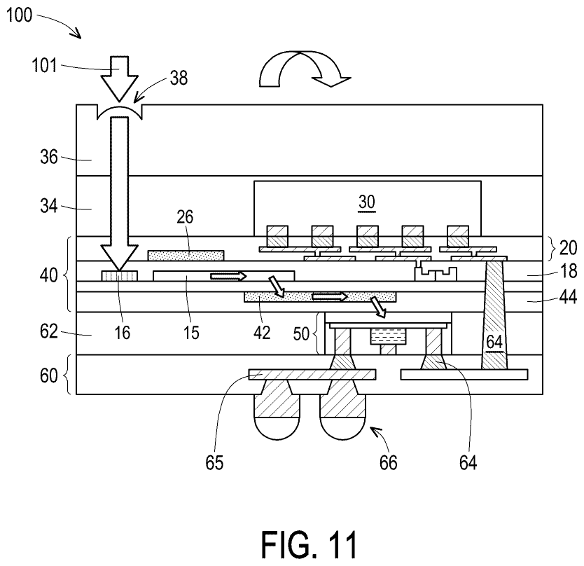

FIGS. 1 through 11 illustrate intermediate steps in the formation of an optical engine 100 (see FIG. 11), in accordance with some embodiments. The optical engine 100 comprises waveguides, photonic components, and integrated circuits that may be configured to receive, generate, modify, transmit, and/or process optical signals. In some embodiments, the optical engine 100 provides an input/output (I/O) interface between optical signals and electrical signals in a package or package component. In some embodiments, the optical engine 100 provides an optical network for signal communication between various components (e.g., photonic devices, integrated circuits, couplings to external fibers, etc.). In this manner, the optical engine 100 can enable optical-electrical (OE) conversion for package-level optical communication (e.g., within a package). The optical engine 100 as described herein can provide high-speed optical signal modulation and/or optical signal detection, enabling data rates greater than about 400 Gbps. In some cases, the optical engine 100 may be considered a photonic package component, an optical package module, a silicon photonic chip, or the like.

Turning to FIG. 1, the optical engine 100 comprises at this stage a substrate 10, a dielectric layer 12, and photonic layer 14, in accordance with some embodiments. In an embodiment, at a beginning of the manufacturing process of the optical engine 100, the substrate 10, the dielectric layer 12, and the photonic layer 14 may collectively be part of a silicon-on-insulator (SOI) substrate or the like, which may be doped (e.g., with a p-type or an n-type dopant) or undoped. In some embodiments, the substrate 10 may be a wafer, such as a silicon wafer. Other substrates, such as a silicon-on-insulator (SOI) substrate, a multi-layered substrate, or a gradient substrate may also be used. In some embodiments, the semiconductor material of the substrate 10 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 10 may be a dielectric material such as silicon oxide, glass, ceramic, plastic, or any other suitable material that allows for structural support of overlying devices. Other substrates, such as a multi-layered or gradient substrate, may also be used. The substrate 10 may be free of passive or active devices, in some cases. In some embodiments, multiple optical engines 100 are formed on a single substrate 10 and then are subsequently singulated into individual optical engines 100.

The dielectric layer 12 may be a dielectric layer that separates the substrate 10 from the overlying photonic layer 14. In some embodiments, the dielectric layer 12 can also serve as an insulating layer or as a portion of cladding material that surrounds the subsequently manufactured photonic components (described below). In an embodiment, the dielectric layer 12 may be silicon oxide, silicon nitride, germanium oxide, germanium nitride, the like, or a combination thereof. The dielectric layer 12 may be formed using a technique such as implantation (e.g., to form a buried oxide (BOX) layer) or using a suitable deposition technique such as chemical vapor deposition (CVD), atomic layer deposition (ALD), physical vapor deposition (PVD), combinations of these, or the like. The dielectric layer 12 may be deposited to a thickness of between about 1,000 Å and about 5,000 Å, in some embodiments. However, any suitable material, thickness, or method of manufacture may be used.

The photonic layer 14 is formed over the dielectric layer 12. In some embodiments, the photonic layer 14 may be a semiconductor material such as silicon, germanium, silicon germanium, the like, or a combination thereof. In other embodiments, the photonic layer 14 may comprise a dielectric material such as silicon nitride or the like, a III-V semiconductor material, a compound semiconductor material, lithium niobate materials, polymers, the like, or a combination thereof. The photonic layer 14 may be formed using a suitable technique, such as epitaxial growth, CVD, ALD, PVD, the like, or combinations thereof. In other embodiments, the photonic layer 14 may be a material suitable for forming optical waveguides, such as silicon nitride or the like. Other materials or techniques are possible. In some cases, the photonic layer 14 may be considered an “active layer,” and “optical layer,” a “core layer,” or the like.

FIG. 2 illustrates the formation of photonic components from the photonic layer 14, in accordance with some embodiments. In some embodiments, the photonic components may include such devices or components as optical waveguides (e.g., ridge waveguides, rib waveguides, buried channel waveguides, diffused waveguides, etc.), couplers (e.g., grating couplers, edge couplers, or other external couplers), evanescent couplers, directional couplers, optical modulators (e.g., germanium modulators, Mach-Zehnder silicon-photonic switches, microelectromechanical switches, micro-ring resonators, etc.), amplifiers, multiplexors, demultiplexors, optical-to-electrical converters (e.g., photodetectors, P-N junctions, or the like), electrical-to-optical converters, lasers (e.g., laser diodes), phase shifters, combinations of these, or the like. As example photonic components, FIG. 2 illustrates a silicon waveguide 15, a grating coupler 16, and an optical device 17. The silicon waveguide 15 may be, for example, a strip waveguide that is about 270 nm thick, though other waveguides are possible. Some photonic components may be optically coupled such that optical signals and/or optical power may be transmitted between the photonic components. For example, the silicon waveguide 15 may be optically coupled to the grating coupler 16. A different number of photonic components may be present, and the photonic components may comprise other devices, structures, or components than the above examples.

In some embodiments, the photonic components may be formed by patterning the photonic layer 14 into the appropriate shapes for the photonic components. For example, photonic layer 14 may be patterned using one or more photolithographic masking and etching processes, though any suitable methods of patterning the photonic layer 14 may be utilized. The patterning may expose portions of the dielectric layer 12. In some cases, additional processing steps may be performed to form some types of photonic components, such as additional implantation processes, deposition processes, epitaxial growth processes, and/or patterning processes. In some embodiments, one or more photonic components may be formed by patterning the photonic layer 14 and then depositing another material on portions of the patterned photonic layer 14. For example, the formation of a photonic components may comprise patterning a photonic layer 14 comprising silicon and then epitaxially growing a region of germanium on the patterned photonic layer 14. Other materials, techniques, or process steps are possible.

Still referring to FIG. 2, a dielectric layer 18 may be formed over the dielectric layer 12 and/or the photonic components, in accordance with some embodiments. The dielectric layer 18 may be, for example, a dielectric material or insulating material that separates the individual photonic components from each other and from the overlying structures. Further, in some cases, the dielectric layer 18 can serve as a cladding material that at least partially surrounds one or more photonic components. In some embodiments, the dielectric layer 18 may comprise silicon oxide, silicon nitride, germanium oxide, germanium nitride, combinations of these, or the like, which may be formed using suitable deposition techniques such as CVD, ALD, PVD, or the like. Other materials or deposition techniques are possible. In some embodiments, after depositing the dielectric layer 18, a planarization process (e.g., a chemical mechanical polishing (CMP) process, a grinding process, or the like) may be performed to planarize a top surface of the dielectric layer 18. In some embodiments, the planarization process may expose a top surface of one or more photonic components. In such embodiments, top surfaces of some photonic components and top surfaces of the dielectric layer 18 may be level or coplanar (within process variations). In some embodiments, one or more photonic components remain covered by the dielectric layer 18 after performing the planarization process.

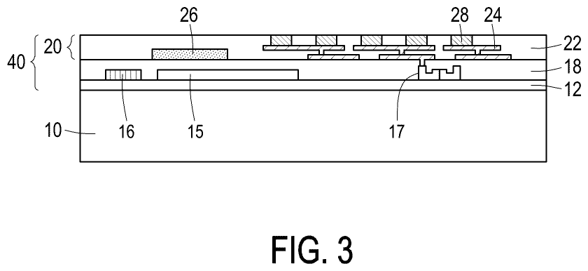

FIG. 3 illustrates the formation of an interconnect structure 20 over the photonic components, in accordance with some embodiments. The interconnect structure 20 includes dielectric layers 22 (not individually illustrated) with conductive features 24 formed in the dielectric layers 22, in some embodiments. The conductive features 24 allow for electrical communication within the optical engine 100. The conductive features 24 may comprise conductive lines, conductive vias, conductive pads, metallization patterns, redistribution layers, or the like that provide electrical interconnections and electrical routing within the optical engine 100. Some conductive features 24 may be electrically connected to one or more photonic components, in some cases. The interconnect structure 20 may also comprise conductive pads 28 at a top surface of the interconnect structure 20, in some embodiments. The conductive pads 28 may be metal pads, bonding pads, or the like.

In some embodiments, the interconnect structure 20 is formed of alternating layers of dielectric material (e.g., dielectric layers 22) and conductive material (e.g., conductive features 24). The conductive features 24 may be formed using any suitable processes such as deposition, damascene, dual damascene, or the like. In particular embodiments, the interconnect structure 20 may have multiple layers of conductive features 24, but the precise number of layers of conductive features 24 may be dependent upon the design of the optical engine 100. The dielectric layers 22 may be, for example, insulating layers and/or passivating layers, and may comprise silicon oxide, silicon nitride, a polymer, a molding material, the like, or a combination thereof. The conductive features 24 may include, for example, a metal or a metal alloy such as copper, silver, gold, tungsten, cobalt, ruthenium, aluminum, alloys thereof, combinations thereof, or the like. Other materials or formation techniques are possible.

In some embodiments, the conductive pads 28 are formed in the topmost dielectric layer 22 (not separately illustrated) of the dielectric layers 22. In some embodiments, the conductive pads 28 may include via portions (not separately illustrated) that physically and electrically contact underlying conductive features 24. In some embodiments, the topmost dielectric layer 22 of the interconnect structure 20 may be a material suitable for dielectric-to-dielectric bonding, such as silicon oxide, silicon nitride, silicon oxynitride, or the like. Other materials are possible. In some embodiments, the conductive pads 28 may be formed by first forming openings (not separately illustrated) in the topmost dielectric layer 22 that expose conductive portions of some underlying conductive features 24, depositing an optional liner in the openings, and then depositing a conductive material in the openings. The conductive material may be similar to those described for the conductive features 24. For example, the conductive material may be copper or a copper alloy, in some embodiments. A planarization process (e.g., a CMP process or a grinding process) may be performed to remove excess conductive material such that top surfaces of the conductive pads 28 and the topmost dielectric layer 22 are approximately level. This is an example, and the conductive pads 28 may be formed using other materials, techniques, or process steps.

Additionally, during the manufacture of the interconnect structure 20, one or more photonic components 26 may be formed within the dielectric layers 22, in accordance with some embodiments. The photonic components 26 may be similar to the photonic components described previously. For example, in some embodiments, the photonic components 26 may include waveguides (e.g., silicon nitride waveguides), couplers, or the like. In some cases, one or more photonic components 26 may be optically coupled to each other and/or to one or more underlying photonic components within the dielectric layer 18. For example, in some embodiments, a photonic component 26 may be a silicon nitride waveguide that is optically coupled to an underlying silicon waveguide 15 by, e.g., evanescent optical coupling. The photonic component 26 may be, for example, a silicon nitride strip waveguide that is about 400 nm thick, though other waveguides are possible.

In some embodiments, photonic components 26 may be formed during the manufacture of the interconnect structure 20 by depositing a material for photonic components 26 on a dielectric layer 22. The material for the photonic components 26 may be a dielectric material such as silicon nitride, silicon oxide, silicon oxynitride, polymer, combinations of these, or the like, or a semiconductor material such as silicon, germanium, or the like. The material may then be patterned into suitable shapes for the photonic components 26 using suitable photolithography and etching techniques. Another dielectric layer 22 may then be deposited on the photonic components 26. In particular embodiments, the interconnect structure 20 may have multiple layers of photonic components 26, but the precise number of layers of photonic components 26 may be dependent upon the design of the optical engine 100.

In some cases, the various dielectric layers (e.g., layers 12, 18, and 22), photonic components (e.g., components 15, 16, 17, and 26), and the interconnect structure 20 may be considered a “photonic wafer,” a “photonic integrated circuit” (PIC), or the like. Accordingly, for convenient reference, some figures indicate a PIC 40. The PIC 40 may include other layers, components, or features than shown.

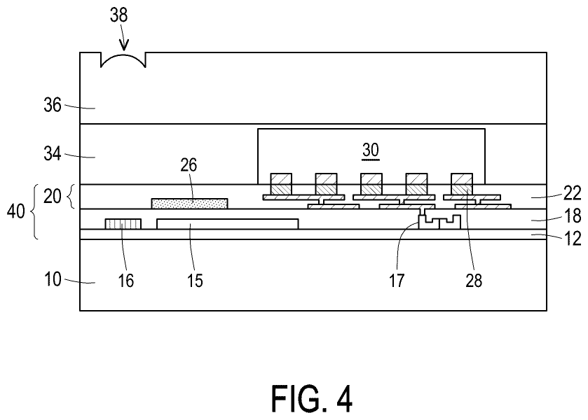

In FIG. 4, an electronic die 30 is bonded to the interconnect structure 20 of the PIC 40, in accordance with some embodiments. The electronic die 30 may be, for example, a semiconductor device, die, component, or chip that may comprise integrated circuits and may interact with various components of the optical engine 100 using electrical signals. The various components may include, for example, photonic components, photonic dies (e.g., photodetector dies, modulator dies, or the like), or the like. For example, the electronic die 30 may include controllers, drivers, transimpedance amplifiers, transistors, other active devices, resistors, capacitors, other passive devices, the like, or combinations thereof. Accordingly, the electronic die 30 may be considered an electronic integrated circuit (EIC) structure or the like. In some embodiments, the electronic die 30 may process electrical signals received from photonic dies (or photonic components, photonic devices, etc.), may control the operation of the photonic dies, and/or may generate electrical signals that photonic dies convert into optical signals. One electronic die 30 is shown in FIG. 4, but an optical engine 100 may include two or more electronic dies 30 in other embodiments.

In some embodiments, the electronic die 30 may provide Serializer/Deserializer (SerDes) functionality. In this manner, the electronic die 30 may act as part of an I/O interface between optical signals and electrical signals within the optical engine 100 or within a package or package component comprising the optical engine 100. In some embodiments, an electronic die 30 may comprise one or more processing devices, such as a Central Processing Unit (CPU or “xPU”), a Graphics Processing Unit (GPU), an Application-Specific Integrated Circuit (ASIC), a High-Performance Computing (HPC) die, a logic die, the like, or a combination thereof. An electronic die 30 may include one or more memory devices, which may be a volatile memory such as Dynamic Random-Access Memory (DRAM), Static Random-Access Memory (SRAM), High-Bandwidth Memory (HBM), another type of memory, or the like. Other electronic dies 30 or configurations thereof are possible.

In some embodiments, the electronic die 30 may include bond pads formed in a bonding layer, and the electronic die 30 is bonded to the interconnect structure 20 by dielectric-to-dielectric bonding and/or metal-to-metal bonding (e.g., direct bonding, fusion bonding, oxide-to-oxide bonding, hybrid bonding, or the like). In some embodiments, a bonding layer (e.g., an exposed dielectric layer) of the electronic die 30 is bonded to a bonding layer (e.g., an exposed dielectric layer, such as the top-most dielectric layer 22) of the interconnect structure 20 using a dielectric-to-dielectric bonding process, and conductive pads of the electronic die 30 are bonded to corresponding conductive pads 28 of the interconnect structure 20 using a metal-to-metal bonding process. In some embodiments, the bonding process may be initiated by activating the bonding surfaces of the electronic die 30 and the interconnect structure 20, which can facilitate bonding of the bonding surfaces. Activating the bonding surfaces may comprise, for example, a dry treatment, a wet treatment, a plasma treatment, exposure to an inert gas plasma, exposure to H₂, exposure to N₂, exposure to O₂, combinations thereof, or the like. For embodiments in which a wet treatment is used, an RCA cleaning process may be used, for example. In other embodiments, the activation process may comprise other types of treatments. After the activation process, the electronic die 30 is aligned and placed into physical contact with the interconnect structure 20. The electronic die 30 and the interconnect structure 20 are then subjected to a thermal treatment and contact pressure to bond respective bonding layers together with dielectric-to-dielectric bonding and bond the conductive pads of the electronic die 30 to the conductive pads 28 of the interconnect structure 20 with metal-to-metal bonding. In some embodiments, the resulting bonded structure is subsequently baked, annealed, pressed, or otherwise treated to strengthen or finalize the bond. This is an example, and other bonding processes are possible. In other embodiments, the electronic dies 30 may comprise conductive connectors (e.g. solder bumps or the like), and may be bonded to the interconnect structure 20 using these conductive connectors.

Further in FIG. 4, a dielectric material 34 is formed over the electronic die 30 and the interconnect structure 20, in accordance with some embodiments. The dielectric material 34 may be formed of silicon oxide, silicon nitride, a polymer, the like, or a combination thereof. The dielectric material 34 may be formed by CVD, PVD, ALD, a spin-on process, the like, or a combination thereof. In some embodiments, the dielectric material 34 may be formed by HDP-CVD, FCVD, PECVD, the like, or a combination thereof. The dielectric material 34 may be a gap-fill material in some embodiments, which may include one or more of the example materials above. In some embodiments, the dielectric material 34 may be a material (e.g., silicon oxide) that is substantially transparent to light at wavelengths suitable for transmitting optical signals or optical power. For example, the dielectric material 34 may allow optical signals or optical power to be transmitted between a photonic component (e.g., grating coupler 16 or the like) and an overlying optical fiber, fiber array unit, or the like. The dielectric material 34 may be a material similar to that of the dielectric layers 22 and/or the dielectric layer 18, in some embodiments. Other dielectric materials formed by any acceptable processes may be used. The dielectric material 34 may be planarized using a planarization process such as a CMP process, a grinding process, or the like. In other embodiments, the planarization process may expose the electronic die 30 such that surfaces of the electronic die 30 and the dielectric material 34 are coplanar.

Further in FIG. 4, a support 36 is attached to the structure, in accordance with some embodiments. The support 36 is a rigid structure that is attached to the structure in order to provide structural or mechanical stability. The use of a support 36 can reduce warping or bending, which can improve the performance of the photonic components within the optical engine 100. The support 36 may be attached to the structure (e.g., to the dielectric material 34 and/or the electronic die 30) using a bonding layer (not illustrated) formed over the dielectric material 34 and the electronic die 30, in accordance with some embodiments. The bonding layer may be an adhesive layer, in some embodiments. In other embodiments, the bonding layer may be a dielectric layer suitable for dielectric-to-dielectric bonding of the support 36. For example, the bonding layer may be deposited on the dielectric material 34 and the electronic die 30, and then the support 36 may be bonded to the bonding layer using suitable dielectric-to-dielectric bonding techniques.

In some embodiments, the support 36 is formed of materials transparent to relevant wavelengths of light such that optical signals may be transmitted through the support 36. In some embodiments, a lens 38 is formed in the upper surface of the support 36. The lens 38 may be optically coupled to a photonic component through the support 36. In some embodiments, the lens 38 facilitates optical coupling between a photonic component (e.g., grating coupler 16 or the like) and an overlying optical fiber, fiber array unit, or the like. In some embodiments, the lens 38 is formed in the support 36 using one or more patterning steps, which may include suitable photolithography and etching processes. In this manner, the lens 38 may comprise a recess or the like in the top surface of the support 36. In other embodiments, the lens 38 is formed separately and is attached to the support 36. In some embodiments, an index-matching material or the like (not illustrated) is deposited over the lens 38. In some embodiments, a support 36 may include multiple lenses 38. The lens 38 shown in FIG. 4 is an example, and lenses 38 may be lens structures having other shapes or sizes than shown.

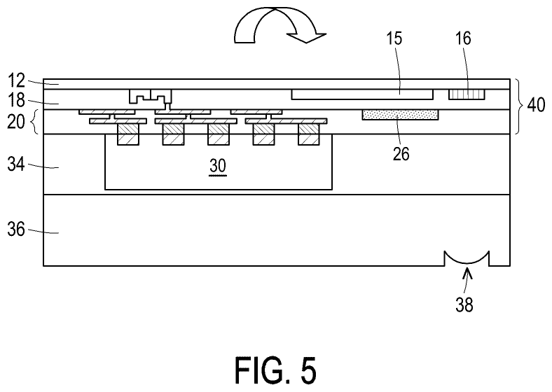

In FIG. 5, the substrate 10 is removed, in accordance with some embodiments. The structure may be flipped over, as shown in FIG. 5. The substrate 10 may be removed using a planarization process (e.g., a CMP process, a grinding process, or the like) and/or an etching process. In some embodiments, removing the substrate 10 exposes the dielectric layer 12. Removing the substrate 10 may include thinning the dielectric layer 12, in some embodiments. A thinned dielectric layer 12 may have a thickness in the range of about 2000 Å to about 3000 Å, though other thicknesses are possible. In some embodiments, the dielectric layer 12 is used as a stop layer during removal of the substrate 10. In other embodiments, the dielectric layer 12 is removed.

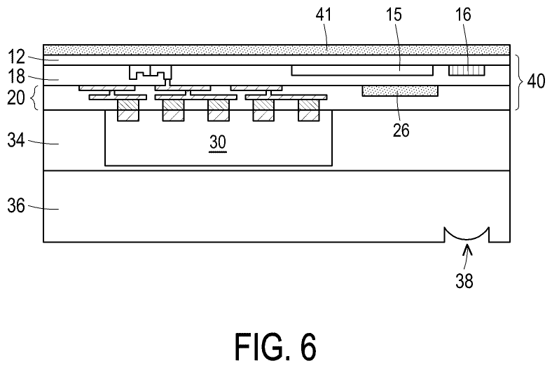

In FIG. 6, a photonic material 41 is deposited over the dielectric layer 12, in accordance with some embodiments. The photonic material 41 may be a dielectric material such as silicon nitride, silicon oxide, silicon oxynitride, polymer, combinations of these, or the like. In other embodiments, the photonic material 41 may be a semiconductor material such as silicon, germanium, or the like. The photonic material 41 may be deposited using a suitable technique, such as CVD, ALD, PVD, or the like. For example, the photonic material 41 may be silicon nitride having a thickness in the range of about 3000 Å to about 5000 Å, though other materials or thicknesses are possible.

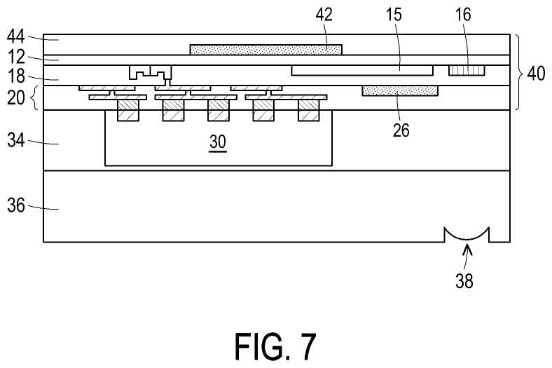

In FIG. 7, waveguides 42 are formed from the photonic material 41, in accordance with some embodiments. For example, the waveguides 42 may be a silicon nitride waveguides having a thickness of about 400 nm, though other waveguides 42 are possible. More than one waveguide 42 may be formed from the photonic material 41. In some embodiments, photonic components such as grating couplers, edge couplers, evanescent couplers, or the like are also formed from the photonic material 41 and may be optically coupled to the waveguides 42. The waveguides 42 may be formed by patterning the photonic material 41 using suitable photolithography and etching techniques.

A dielectric layer 44 may then be deposited over the waveguides 42. The dielectric layer 44 may be a material similar to the dielectric layer 18 or the dielectric layers 22. In some embodiments, the dielectric layer 44 is a material suitable for dielectric-to-dielectric bonding, such as silicon oxide or the like. Accordingly, the dielectric layer 44 may be considered a bonding layer of the PIC 40, in some cases. A planarization process (e.g., a CMP or grinding process) may be performed on the dielectric layer 44, in some embodiments. After performing the planarization process, a thickness of the dielectric layer 44 over the waveguides 42 may be less than about 200 nm, in some embodiments, though other thicknesses are possible. The steps of depositing a photonic material, patterning the photonic material to form a layer of waveguides, and then depositing a dielectric layer over the layer of waveguides may be repeated to form multiple layers of waveguides. In some cases, the waveguides 42, other waveguides formed from photonic material(s), and/or photonic components formed from photonic material(s) are considered part of the PIC 40.

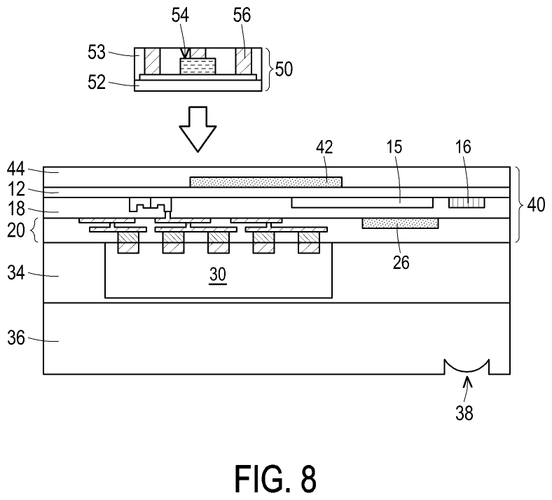

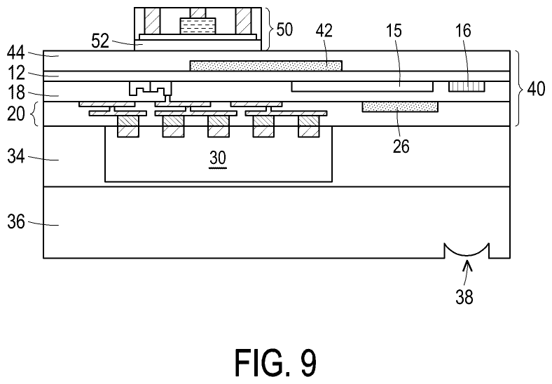

FIGS. 8 and 9 illustrate the bonding of a photodetector die 50 to the PIC 40, in accordance with some embodiments. FIG. 7 illustrates the photodetector die 50 prior to bonding, and FIG. 8 illustrates the structure after the photodetector die 50 has been bonded to the PIC 40. In some embodiments, the photodetector die 50 may comprise a photodetector based on a III-V semiconductor material or compound semiconductor material, such as gallium arsenide (GaAs), indium gallium arsenide (InGaAs), or the like. Other photodetector materials, such as germanium, may also be used in other embodiments. In some cases, the particular semiconductor material or composition thereof may depend on the wavelength(s) of light used by optical signals or optical power within the optical engine 100. Forming the photodetector die 50 separately and bonding it to the PIC 40 can allow for the use of photodetector materials that may be difficult to fabricate within the PIC 40, such as some III-V semiconductor materials. Accordingly, an optical engine 100 can benefit from the improved speed, sensitivity, bandwidth, or efficiency afforded by a photodetector die 50 that utilizes these photodetector materials.

In some embodiments, the photodetector die 50 includes a bonding layer 52. The bonding layer 52 comprises a material suitable for direct bonding to the dielectric layer 44. For example, in some embodiments, the bonding layer 52 comprises silicon oxide, indium phosphide, or the like. The bonding layer 52 may comprise multiple layers, with at least the outermost (e.g., bottom) layer being a material suitable for direct bonding. Over the bonding layer 52 is a photodetector 54, which may comprise one or more materials including the photodetector materials described above. In some embodiments, the photodetector 54 includes a waveguide (not separately labeled), and the photodetector 54 is configured to detect or respond to optical signals or optical power within the waveguide. In some embodiments, a photodetector die 50 includes multiple photodetectors 54. The photodetector 54 may be covered by one or more dielectric layers 53, which may be similar to the dielectric layers described previously, or may comprise a different material. The photodetector die 50 also includes vias 56, which extend through the dielectric layers 53 to electrically contact the photodetector 54 to allow electrical signals or electrical power to be transmitted to or from the photodetector 54. In some embodiments, the photodetector die 50 has a thickness in the range of about 2 μm to about 4 μm, though other thicknesses are possible. The photodetector die 50 may comprise integrated circuits, electrical interconnects, or other appropriate features that are not illustrated in FIG. 8. Accordingly, the illustrated photodetector die 50 is a representative example, and other configurations or structures are possible. In some cases, a photodetector die 50 may comprise photonic components in addition to a photodetector 54.

Referring to FIG. 9, the photodetector die 50 is bonded to the PIC 40, in accordance with some embodiments. The photodetector die 50 may be bonded to the PIC 40 using a direct bonding process, such as a dielectric-to-dielectric bonding process. In a particular embodiment which utilizes a dielectric-to-dielectric bonding process, the process may be initiated by activating the bonding surfaces of the photodetector die 50 and the PIC 40, such as the surface of the bonding layer 52 of the photodetector die 50 and the surface of the dielectric layer 44 of the PIC 40. Activating the bonding surfaces of the photodetector die 50 and the PIC 40 may comprise a dry treatment, a wet treatment, a plasma treatment, exposure to an inert gas plasma, exposure to H₂, exposure to N₂, exposure to O₂, the like, or a combination thereof. For embodiments in which a wet treatment is performed, an RCA cleaning may be used, for example. The activation process may comprise other types of treatments in other embodiments. The activation process facilitates bonding of the photodetector die 50 to the PIC 40.

After the activation process, the bonding layer 52 and the dielectric layer 44 may be cleaned using, e.g., a chemical rinse or the like. The photodetector die 50 is then aligned and placed into physical contact with the dielectric layer 44. The photodetector die 50 and the PIC 40 are then subjected to thermal treatment and contact pressure to bond the photodetector die 50 and the PIC 40. For example, the photodetector die 50 and the dielectric layer 44 may be subjected to a pressure of about 200 kPa or less and a temperature between about 25° C. and about 250° C. to fuse the bonding layer 52 and the dielectric layer 44. In this manner, the photodetector die 50 and the PIC 40 form a dielectric-to-dielectric bonded structure. In some embodiments, the bonded structure is subsequently baked, annealed, pressed, or otherwise treated to strengthen or finalize the bond. Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

In some embodiments, the photodetector die 50 may be aligned to a waveguide 42 such that the photodetector die 50 is optically coupled to the waveguide 42. For example, the photodetector die 50 may overlap a waveguide 42 such that the waveguide 42 is evanescently coupled to the photodetector 54 of the photodetector die 50. In this manner, optical signals and/or optical power may be transmitted between the PIC 40 and the photodetector die 50. Bonding the photodetector die 50 to the PIC 40 using direct bonding as described herein can allow for improved optical coupling between the photodetector die 50 and the PIC 40. In some embodiments, one or more photodetector dies 50 may be bonded to the PIC 40 and optically coupled to one or more waveguides 42.

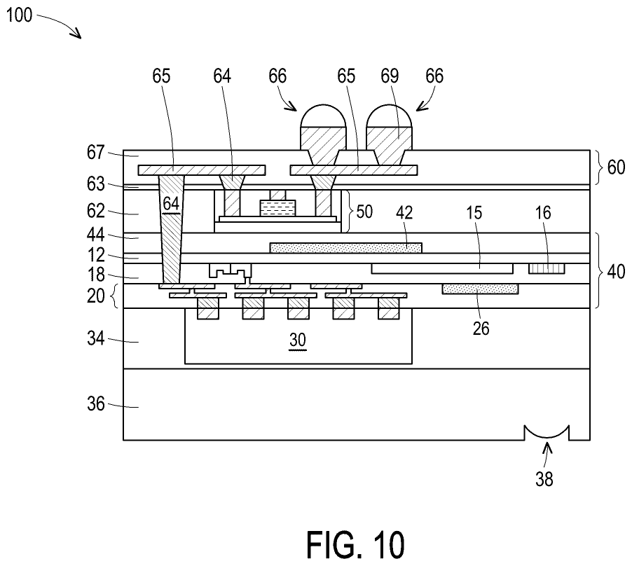

FIG. 10 illustrates the formation of additional layers and conductive features, forming an optical engine 100, in accordance with some embodiments. After bonding the photodetector die 50 to the PIC 40, a dielectric material 62 may be deposited over the dielectric layer 44 and around the photodetector die 50. In some cases, the dielectric material 62 may be a gap-fill material or the like that fills space and provides additional structural support. In some embodiments, the dielectric material 62 is a material such as silicon oxide, silicon nitride, silicon oxynitride, the like, or a combination thereof, and may be deposited using a suitable technique. In some embodiments, a planarization process (e.g., a CMP or grinding process) may be performed to remove excess dielectric material 62. In some cases, the planarization process may expose a top surface of the photodetector die 50, such that surfaces of the photodetector die 50 and the dielectric material 62 are substantially level or coplanar.

In some embodiments, an optional dielectric layer 63 is deposited over the dielectric material 62 and the photodetector die 50. The dielectric layer 63 may be an etch stop layer, in some cases. The dielectric layer 63 may be a suitable material such as silicon nitride, silicon oxide, a metal oxide, the like, or a combination thereof. In some embodiments, the dielectric layer 63 has a thickness in the range of about 1000 Å to about 3000 Å, though other thicknesses are possible. In other embodiments, the dielectric layer 63 is omitted.

An interconnect structure 60 may be formed over the dielectric layer 63, in some embodiments. The interconnect structure 60 includes one or more dielectric layers 67 (not individually illustrated) with one or more layers of conductive features 65 formed in the dielectric layers 67, in some embodiments. FIG. 10 illustrates a single layer of conductive features 65, but multiple layers of conductive features 65 may be formed in other embodiments. The conductive features 65 allow for electrical communication within the optical engine 100. The conductive features 24 may comprise conductive lines, conductive vias, conductive pads, metallization patterns, redistribution layers, or the like that provide electrical interconnections and electrical routing within the optical engine 100. Some conductive features 65 may be electrically connected to one or more photonic components and/or to the photodetector die(s) 50, in some cases.

In some embodiments, the interconnect structure 60 is formed of alternating layers of dielectric material (e.g., dielectric layers 67) and conductive material (e.g., conductive features 65). The conductive features 65 may be formed using any suitable processes such as deposition, damascene, dual damascene, or the like. In particular embodiments, the interconnect structure 60 may have multiple layers of conductive features 65, but the precise number of layers of conductive features 65 may be dependent upon the design of the optical engine 100. The dielectric layers 67 may be, for example, insulating layers and/or passivating layers, and may comprise silicon oxide, silicon nitride, a polymer, a molding material, the like, or a combination thereof. In some cases, the dielectric layers 67 may include passivation layers or bonding layers. The conductive features 65 may include, for example, a metal or a metal alloy such as copper, silver, gold, tungsten, cobalt, ruthenium, aluminum, alloys thereof, combinations thereof, or the like. Other materials or formation techniques are possible.

In some embodiments, vias 64 are formed extending through dielectric layer(s) 67, the dielectric layer 63, and/or other underlying dielectric layers, in accordance with some embodiments. The vias 64 may physically and electrically contact conductive features 65 of the interconnect structure 60, vias 56 of the photodetector die 50, and/or conductive features 24 of the interconnect structure 20. In this manner, the vias 64 provide some electrical connections between the PIC 40, the EIC 30, the photodetector die 50, and the interconnect structure 60. In some embodiments, one or more vias 64 extend through the bonding layer 52, the dielectric layer 44, the dielectric layer 12, and the dielectric layer 18 to contact conductive features 24 of the interconnect structure 20, and in some embodiments some vias 64 may extend into one or more of the dielectric layers 22 of the interconnect structure 20.

The vias 64 may be formed, for example, by forming openings that expose surfaces of the conductive features 24 of the interconnect structure 20 or the vias 56 of the photodetector die 50. The openings may be formed using acceptable photolithography and etching techniques, such as by forming and patterning a photoresist and then performing an etching process using the patterned photoresist as an etching mask. The etching process may include, for example, a dry etching process and/or a wet etching process. Conductive material may then be deposited in the openings, thereby forming the vias 64. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive, such that surfaces of the vias 64 and a dielectric layer 67 are level. Conductive features 65 may be formed over the vias 64, and may directly contact the vias 64. Other materials or techniques are possible. In other embodiments, the vias 64 are formed at another stage of the manufacturing process than described above.

Further in FIG. 10, conductive connectors 66 are formed on the interconnect structure 60, in accordance with some embodiments. The conductive connectors 66 may be used to electrically connect the optical engine 100 to an external structure such as a package substrate, an organic core substrate, an interposer, or the like. In some embodiments, under-bump metallizations (UBMs) 69 are formed within the interconnect structure 60 to make physical and electrical contact to conductive features 65 within the interconnect structure 60. In some embodiments, the UBMs 69 have bump portions on and extending along a major surface of a dielectric layer 67, such as the top-most dielectric layer 67. The UBMs 69 may be formed of one or more conductive materials using a suitable process, such as plating. In some embodiments, the UBMs 69 are not formed.

The conductive connectors 66 are then formed on the UBMs 69, in accordance with some embodiments. The conductive connectors 66 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 66 may include a conductive material such as solder, copper, aluminum, gold, nickel, silver, palladium, tin, the like, or a combination thereof. In some embodiments, the conductive connectors 66 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 66 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In other embodiments, the conductive connectors 66 are omitted and the UBMs 69 are bonding pads used for metal-to-metal bonding to an external component. In this manner, an optical engine 100 may be formed. The optical engine 100 shown in FIG. 10 is an example, and other process steps, materials, configurations, or arrangements are possible.

FIG. 11 illustrates the optical engine 100 of FIG. 10, flipped and annotated with a simplified optical path diagram (represented by arrows 101), in accordance with some embodiments. The arrows 101 represent a possible path of optical signals that enter the optical engine 100 and are received and detected by the photodetector die 50. The optical signals may be transmitted to the optical engine 100 from an optical fiber or the like (not separately illustrated). The optical signals are transmitted through the lens 38, the support 36, the dielectric material 34, and the interconnect structure 20 to the grating coupler 16. The grating coupler 16 receives the optical signals and couples the optical signals into the silicon waveguide 15. The optical signals are then evanescently coupled from the silicon waveguide 15 into the waveguide 42. The optical signals are then evanescently coupled from the waveguide 42 into the photodetector die 50. The photodetector die 50 detects the optical signals and generates corresponding electrical signals, which are transmitted through connected vias 64 into the interconnect structure 60. The electrical signals may be transmitted to the conductive connectors 66 and/or to the electronic die 30. In some cases, electrical signals and/or electrical power may be transmitted to the photodetector die 50, such as electrical signals transmitted from the electronic die 30 or electrical power transmitted from the conductive connectors 66. In other embodiments, optical signals may be coupled between waveguides using grating couplers or other techniques rather than by evanescent coupling. In this manner, the techniques described herein allows for the incorporation of a high-speed photodetector into an optical engine, thus enabling high-bandwidth optical communication.

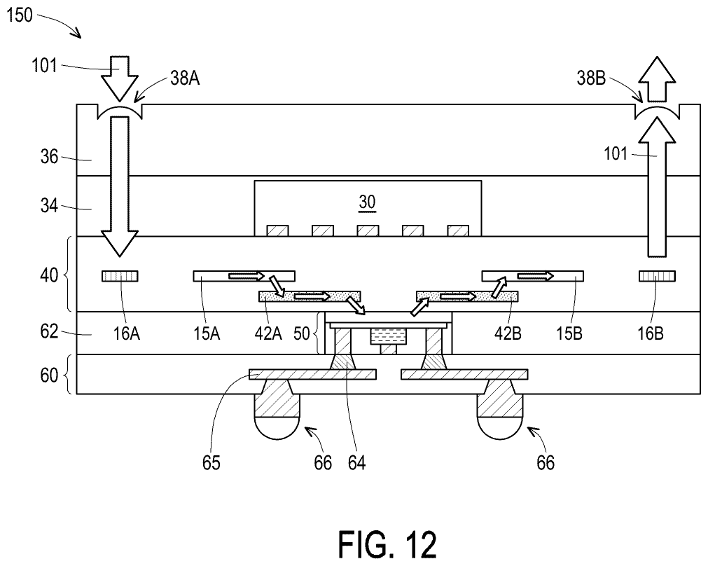

In some cases, some of the optical signals transmitted into the photodetector die 50 may be transmitted out of the photodetector die 50 into other waveguides. As an example, FIG. 12 illustrates an optical engine 150, in accordance with some embodiments. The optical engine 150 is similar to the optical engine 100 of FIG. 11, except that additional waveguides and grating couplers are shown. For example, waveguides 15A-B and grating couplers 16A-B may be similar to the waveguide 15 and grating coupler 16 of the optical engine 100, and waveguides 42A-B may be similar to the waveguide 42 of the optical engine 100. For clarity, some features, including some features shown in FIG. 11, may not be illustrated in FIG. 12. FIG. 12 illustrates a simplified optical path diagram (represented by arrows 101), in accordance with some embodiments. The arrows 101 represent a possible path of optical signals that enter the optical engine 150, are received and detected by the photodetector die 50, and then are transmitted out of the optical engine 150. In some cases, optical signals may be transmitted in either direction along an optical path, and not just in the direction indicated by the arrows 101.

The optical signals may be transmitted to the optical engine 150 from an optical fiber or the like (not separately illustrated). The optical signals are transmitted through the lens 38A, the support 36, and the dielectric material 34 to the grating coupler 16A within the PIC 40. The grating coupler 16A receives the optical signals and couples the optical signals into the silicon waveguide 15A. The optical signals are then evanescently coupled from the silicon waveguide 15A into the waveguide 42A. The optical signals are then evanescently coupled from the waveguide 42A into the photodetector die 50. The photodetector die 50 detects the optical signals and generates corresponding electrical signals. After detection by the photodetector die 50, optical signals may be evanescently coupled into the waveguide 42B. The optical signals may then be evanescently coupled into the waveguide 15B and then into the grating coupler 16B. The grating coupler 16B directs the optical signals upward through the dielectric material 34 and support 36 to the lens 38B. The optical signals may then be coupled by the lens 38B to an external optical component, such as an optical fiber or the like. In this manner, the techniques described herein allows for the incorporation of a high-speed photodetector into an optical engine, thus enabling high-bandwidth optical communication.

In some embodiments, the optical signals may be split such that a portion of the optical signals are received by the photodetector die 50 and a portion of the optical signals are transmitted out of the photodetector die 50 (e.g. into the waveguide 42B). In some embodiments, the optical signals may be split before a portion of the optical signals enter the photodetector die 50. In other embodiments, the optical signals are transmitted to an optical modulator within the optical engine 150 before being transmitted to the photodetector die 50.

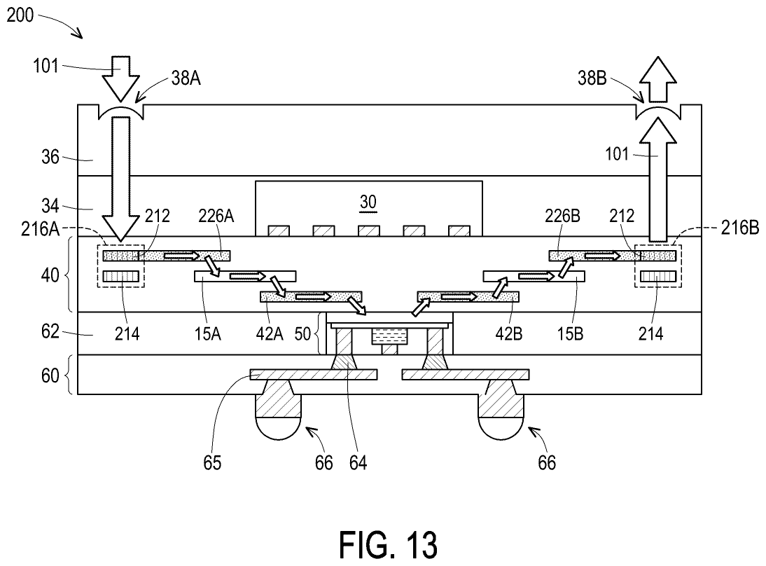

FIG. 13 illustrates an optical engine 200, in accordance with some embodiments. The optical engine 200 is similar to the optical engine 150 of FIG. 12, except that the optical engine 200 transmits optical signals using additional waveguides 226A-B and dual grating couplers 216A-B. FIG. 13 illustrates a simplified optical path diagram (represented by arrows 101), in accordance with some embodiments. The arrows 101 represent a possible path of optical signals that enter the optical engine 200, are received and detected by the photodetector die 50, and then are transmitted out of the optical engine 200.

The waveguides 226A-B may be similar to the waveguides described previously for the photonic components 26 (see FIG. 3). For example, the waveguides 226A-B may be silicon nitride strip waveguides that are about 400 nm thick, though other waveguides are possible. The waveguides 226A-B are optically coupled to underlying silicon waveguides 15A-B by, e.g., evanescent optical coupling. The dual grating couplers 216A-B comprise lower grating coupler features 214A-B formed from the photonic layer 14, similar to the grating couplers 16 described previously. The dual grating couplers 216A-B also comprise upper grating coupler features 212A-B formed from the same material as the waveguides 226A-B. For example, the waveguides 226A-B and the upper grating coupler features 212A-B may be formed by depositing a material layer and then patterning the material layer. The material layer may be, for example, silicon nitride, though other materials are possible. The lower grating coupler features 214A-B and the upper grating coupler features 212A-B may be formed of different materials. In this manner, the dual grating coupler 216A includes a lower grating coupler feature 214A and an upper grating coupler feature 212A, and the dual grating coupler 216B includes a lower grating coupler feature 214B and an upper grating coupler feature 212B. The dual grating coupler 216A is optically coupled to the waveguide 226A, and the dual grating coupler 216B is optically coupled to the waveguide 226B. Another number or configuration of waveguides 226 and/or dual grating couplers 216 are possible.

The optical signals may be transmitted to the optical engine 200 from an optical fiber or the like (not separately illustrated). The optical signals are transmitted through the lens 38A, the support 36, and the dielectric material 34 to the dual grating coupler 216A within the PIC 40. The dual grating coupler 216A receives the optical signals and couples the optical signals into the waveguide 226A. The optical signals are then evanescently coupled from the waveguide 226A into the silicon waveguide 15A. The optical signals are evanescently coupled from the silicon waveguide 15A into the waveguide 42A, and from the waveguide 42A into the photodetector die 50. The photodetector die 50 detects the optical signals and generates corresponding electrical signals. After detection by the photodetector die 50, optical signals may be evanescently coupled into the waveguide 42B. The optical signals may be evanescently coupled into the waveguide 15B and then into the waveguide 226B. The optical signals are coupled into the dual grating coupler 216B from the waveguide 226B. The grating coupler 216B directs the optical signals upward through the dielectric material 34 and support 36 to the lens 38B. The optical signals may then be coupled by the lens 38B to an external optical component, such as an optical fiber or the like. In this manner, the techniques described herein allows for the incorporation of a high-speed photodetector into an optical engine, thus enabling high-bandwidth optical communication.

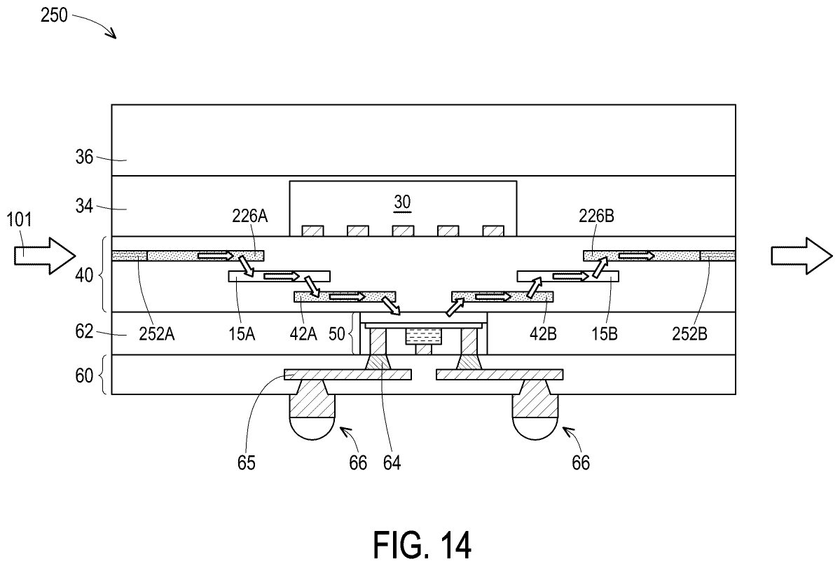

FIG. 14 illustrates an optical engine 250, in accordance with some embodiments. The optical engine 250 is similar to the optical engine 200 of FIG. 13, except that the optical engine 250 uses edge couplers 252A-B to transmit optical signals into and out of the optical engine 250. The edge couplers 252A-B are optically coupled to the waveguides 226A-B. For example, the edge coupler 252A is optically coupled to the waveguide 226A, and the edge coupler 252B is optically coupled to the waveguide 226B. FIG. 14 illustrates a simplified optical path diagram (represented by arrows 101), in accordance with some embodiments. The arrows 101 represent a possible path of optical signals that enter the optical engine 250, are received and detected by the photodetector die 50, and then are transmitted out of the optical engine 200.

The optical signals may be transmitted into the optical engine 250 from an optical fiber or the like (not separately illustrated) attached to a sidewall of the optical engine 250 near the edge coupler 252A. The edge coupler 252A receives the optical signals and couples the optical signals into the waveguide 226A. The optical signals are then evanescently coupled from the waveguide 226A into the silicon waveguide 15A. The optical signals are evanescently coupled from the silicon waveguide 15A into the waveguide 42A, and from the waveguide 42A into the photodetector die 50. The photodetector die 50 detects the optical signals and generates corresponding electrical signals. After detection by the photodetector die 50, optical signals may be evanescently coupled into the waveguide 42B. The optical signals may be evanescently coupled into the waveguide 15B and then into the waveguide 226B. The optical signals are coupled into the edge coupler 252B from the waveguide 226B. The optical signals may then be coupled by the edge coupler 252B to an external optical component, such as an optical fiber or the like. In this manner, the techniques described herein allows for the incorporation of a high-speed photodetector into an optical engine, thus enabling high-bandwidth optical communication.

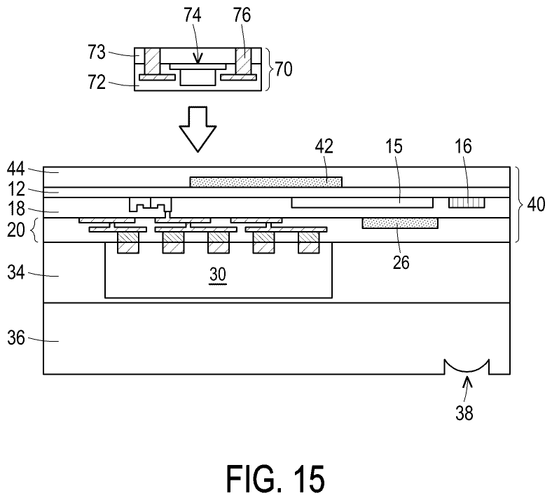

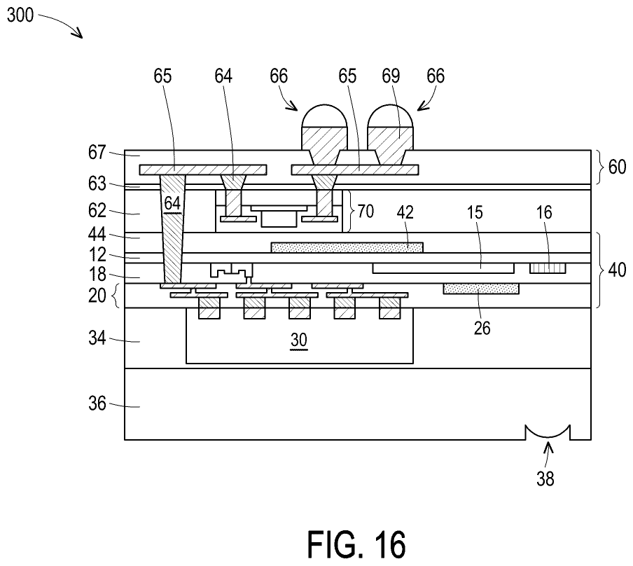

FIGS. 15 and 16 illustrate intermediate stages in the formation of an optical engine 500, in accordance with some embodiments. The optical engine 500 is similar to the optical engine 100 of FIG. 11, except that the optical engine 500 includes a modulator die 70 instead of a photodetector die 50. The optical engine 500 may be formed using some materials and process steps similar to that described previously for the optical engine 100, and, as such, some details may not be repeated.

FIG. 15 illustrates a modulator die 70 prior to being bonded to a PIC 40, in accordance with some embodiments. The PIC 40 may be similar to the PIC 40 described previously. Additionally, an electronic die 30 and a support 36 may be formed over the PIC 40, similar to the structures described previously.

In some embodiments, the modulator die 70 includes a bonding layer 72. The bonding layer 72 comprises a material suitable for direct bonding to the dielectric layer 44. For example, in some embodiments, the bonding layer 72 comprises silicon oxide, indium phosphide, or the like. The bonding layer 72 may comprise multiple layers, with at least the outermost (e.g., bottom) layer being a material suitable for direct bonding. For example, the bonding layer 72 may include a cladding layer or the like. The bonding layer 72 covers the modulator 74, which is configured to receive optical signals or optical power, and modulate the optical signals or optical power based on received electrical signals. The modulator 74 may be any suitable optical modulator, such as a Mach-Zehnder modulator, a Michelson modulator, a phase modulator, or the like. Further, the modulator 74 may be an electro-optic modulator, a thermo-optic modulator, or the like. For example, in some embodiments, the modulator 74 may be a thin-film lithium niobate (TFLN) modulator or the like, though other modulators are possible. In some cases, utilizing a TFLN modulator for the modulator 74 may allow for a thinner modulator die 70. In some embodiments, the modulator 74 includes a waveguide (not separately labeled), and the modulator 74 is configured to detect or respond to optical signals or optical power within the waveguide. For example, in some embodiments, the waveguide may be a lithium niobate rib waveguide having a thickness of about 600 nm, though other materials or thicknesses are possible. In some embodiments, a modulator die 70 includes multiple modulators 74. The modulator 74 may be formed on a substrate 73, which may comprise a dielectric material, a semiconductor material, and/or another suitable material.

The modulator die 70 also includes conductive features 76, which provide electrical connection and electrical operation for the modulator die 70. In some embodiments, the modulator die 70 has a thickness in the range of about 2 μm to about 4 μm, though other thicknesses are possible. The modulator die 70 may comprise integrated circuits, electrical interconnects, or other appropriate features that are not illustrated in FIG. 15. Accordingly, the illustrated modulator die 70 is a representative example, and other configurations or structures are possible. In some cases, a modulator die 70 may comprise photonic components in addition to a modulator 74.

FIG. 16 illustrates the modulator die 70 after bonding to the PIC 40, in accordance with some embodiments. After the bonding, additional processing is performed to form the optical engine 300. In some embodiments, the modulator die 70 is bonded to the PIC 40 using direct bonding, similar to the photodetector die 50. The modulator die 70 may be bonded to the PIC 40 using a dielectric-to-dielectric bonding process. For example, the bonding layer 72 of the modulator die 70 may be bonded to the dielectric layer 44 of the PIC 40. Similar to the photodetector die 50, any suitable combination of baking, annealing, pressing, or combination of processes may be utilized to bond the modulator die 70 to the PIC 40. All such processes are fully intended to be included within the scope of the embodiments.

In some embodiments, the modulator die 70 may be aligned to a waveguide 42 such that the modulator die 70 is optically coupled to the waveguide 42. For example, the modulator die 70 may overlap a waveguide 42 such that the waveguide 42 is evanescently coupled to the modulator 74 of the modulator die 70. In this manner, optical signals and/or optical power may be transmitted between the PIC 40 and the modulator die 70. Bonding the modulator die 70 to the PIC 40 using direct bonding as described herein can allow for improved optical coupling between the modulator die 70 and the PIC 40, and can allow for a thinner optical engine. In some embodiments, one or more modulator dies 70 may be bonded to the PIC 40 and optically coupled to one or more waveguides 42.

Additional process steps may be performed, which may be similar to those described previously for FIG. 10. For example, a dielectric material 62 may be deposited over the modulator die 70, and an optional dielectric layer 63 may be deposited over the dielectric material 62 and the modulator die 70. An interconnect structure 60 may be formed over the dielectric layer 63, in some embodiments. The interconnect structure 60 includes one or more dielectric layers 67 (not individually illustrated) with one or more layers of conductive features 65 formed in the dielectric layers 67, in some embodiments. Vias 64 may be formed that electrically connect the interconnect structure 60, the modulator die 70, and/or the interconnect structure 20. Conductive connectors 66 may be formed on the interconnect structure 60, in accordance with some embodiments.

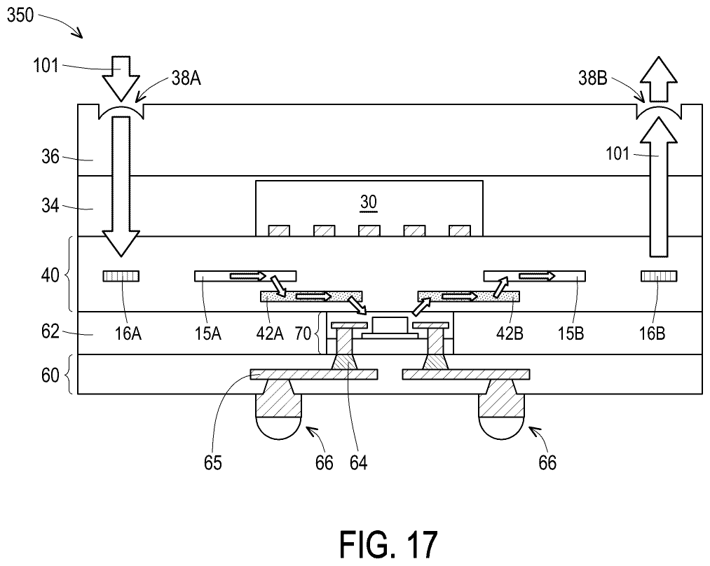

FIG. 17 illustrates an optical engine 350, in accordance with some embodiments. The optical engine 350 is similar to the optical engine 300 of FIG. 16, except that additional waveguides and grating couplers are shown. The optical engine 350 may be similar to the optical engine 150, except that a modulator die 70 is used instead of a photodetector die 50. For clarity, some features, including some features shown in FIG. 16, may not be illustrated in FIG. 17. FIG. 17 illustrates a simplified optical path diagram (represented by arrows 101), in accordance with some embodiments. The arrows 101 represent a possible path of optical signals or optical power that enters the optical engine 350, are received and modulated by the modulator die 70, and then are transmitted out of the optical engine 350. In some cases, optical signals may be transmitted in either direction along an optical path, and not just in the direction indicated by the arrows 101.

The optical signals may be transmitted to the optical engine 350 from an optical fiber or the like (not separately illustrated). The optical signals are transmitted through the lens 38A, the support 36, and the dielectric material 34 to the grating coupler 16A within the PIC 40. The grating coupler 16A receives the optical signals and couples the optical signals into the silicon waveguide 15A. The optical signals are then evanescently coupled from the silicon waveguide 15A into the waveguide 42A. The optical signals are then evanescently coupled from the waveguide 42A into the modulator die 70. The modulator die 70 receives electrical signals and modulates the optical signals based on the electrical signals. The modulated optical signals may be evanescently coupled from the modulator die 70 into the waveguide 42B. The optical signals may then be evanescently coupled into the waveguide 15B and then into the grating coupler 16B. The grating coupler 16B directs the optical signals upward through the dielectric material 34 and support 36 to the lens 38B. The optical signals may then be coupled by the lens 38B to an external optical component, such as an optical fiber or the like. In this manner, the techniques described herein allows for the incorporation of a high-speed modulator into an optical engine, thus enabling high-bandwidth optical communication.

In some embodiments, the optical signals may be split such that a portion of the optical signals are received by the modulator die 70 and a portion of the optical signals are transmitted out of the modulator die 70 (e.g. into the waveguide 42B). In some embodiments, the optical signals may be split before a portion of the optical signals enter the modulator die 70. In other embodiments, the optical signals are transmitted to photodetector within the optical engine 350 after being transmitted to the modulator die 70.

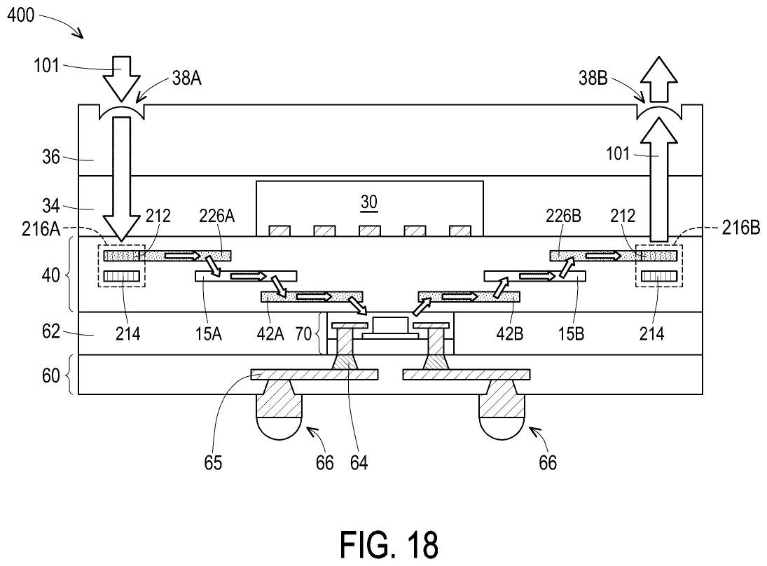

FIG. 18 illustrates an optical engine 400, in accordance with some embodiments. The optical engine 400 is similar to the optical engine 350 of FIG. 17, except that the optical engine 400 transmits optical signals using additional waveguides 226A-B and dual grating couplers 216A-B. The optical engine 400 may be similar to the optical engine 200 of FIG. 13, except that a modulator die 70 is used instead of a photodetector die 50. For example, the waveguides 226A-B and the dual grating couplers 216A-B may be similar to those previously described for FIG. 13. FIG. 18 illustrates a simplified optical path diagram (represented by arrows 101), in accordance with some embodiments. The arrows 101 represent a possible path of optical signals or optical power that enters the optical engine 400, are received and modulated by the modulator die 70, and then are transmitted out of the optical engine 400.

The optical signals may be transmitted to the optical engine 400 from an optical fiber or the like (not separately illustrated). The optical signals are transmitted through the lens 38A, the support 36, and the dielectric material 34 to the dual grating coupler 216A within the PIC 40. The dual grating coupler 216A receives the optical signals and couples the optical signals into the waveguide 226A. The optical signals are then evanescently coupled from the waveguide 226A into the silicon waveguide 15A. The optical signals are evanescently coupled from the silicon waveguide 15A into the waveguide 42A, and from the waveguide 42A into the modulator die 70. The modulator die 70 receives electrical signals and modulates the optical signals based on the electrical signals. The modulated optical signals may be evanescently coupled from the modulator die 70 into the waveguide 42B. The optical signals may be evanescently coupled from the waveguide 42B into the waveguide 15B and then into the waveguide 226B. The optical signals are coupled into the dual grating coupler 216B from the waveguide 226B. The grating coupler 216B directs the optical signals upward through the dielectric material 34 and support 36 to the lens 38B. The optical signals may then be coupled by the lens 38B to an external optical component, such as an optical fiber or the like. In this manner, the techniques described herein allows for the incorporation of a high-speed modulator into an optical engine, thus enabling high-bandwidth optical communication.

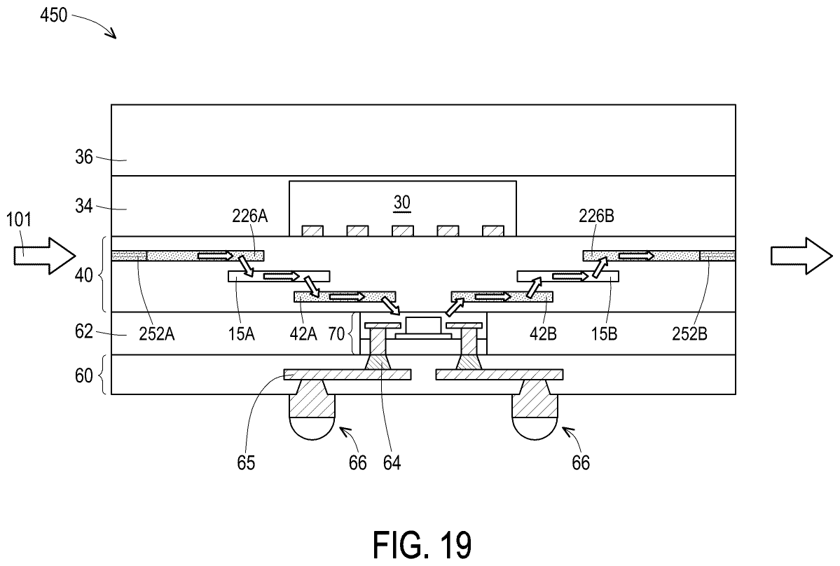

FIG. 19 illustrates an optical engine 450, in accordance with some embodiments. The optical engine 450 is similar to the optical engine 400 of FIG. 18, except that the optical engine 450 uses edge couplers 252A-B to transmit optical signals into and out of the optical engine 450. The optical engine 450 may be similar to the optical engine 250 of FIG. 14, except that a modulator die 70 is used instead of a photodetector die 50. For example, the edge coupler 252A is optically coupled to the waveguide 226A, and the edge coupler 252B is optically coupled to the waveguide 226B. FIG. 19 illustrates a simplified optical path diagram (represented by arrows 101), in accordance with some embodiments. The arrows 101 represent a possible path of optical signals or optical power that enters the optical engine 450, are received and modulated by the modulator die 70, and then are transmitted out of the optical engine 450.

The optical signals may be transmitted into the optical engine 450 from an optical fiber or the like (not separately illustrated) attached to a sidewall of the optical engine 450 near the edge coupler 252A. The edge coupler 252A receives the optical signals and couples the optical signals into the waveguide 226A. The optical signals are then evanescently coupled from the waveguide 226A into the silicon waveguide 15A. The optical signals are evanescently coupled from the silicon waveguide 15A into the waveguide 42A, and from the waveguide 42A into the modulator die 70. The modulator die 70 receives electrical signals and modulates the optical signals based on the electrical signals. The modulated optical signals may be evanescently coupled from the modulator die 70 into the waveguide 42B. The optical signals may be evanescently coupled into the waveguide 15B and then into the waveguide 226B. The optical signals are coupled into the edge coupler 252B from the waveguide 226B. The optical signals may then be coupled by the edge coupler 252B to an external optical component, such as an optical fiber or the like. In this manner, the techniques described herein allows for the incorporation of a high-speed modulator into an optical engine, thus enabling high-bandwidth optical communication.

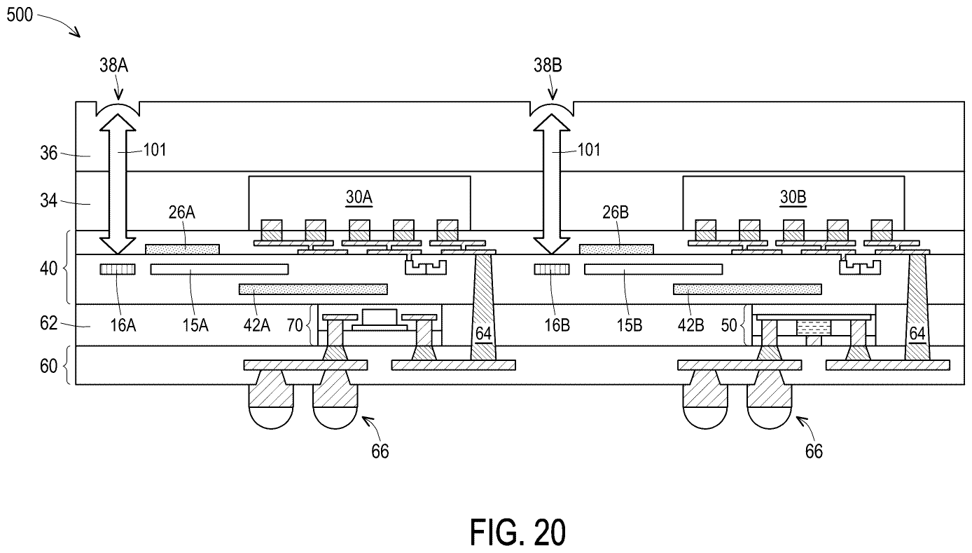

In some embodiments, an optical engine may comprise multiple photonic dies, such as both photodetector dies 50 and modulator dies 70. As an example, FIG. 20 illustrates an optical engine 500 that includes both a photodetector die 50 and a modulator die 70, in accordance with some embodiments. In this manner, both high-speed optical modulation and high-speed optical detection may be achieved in an optical engine. The photodetector die 50 and the modulator die 70 may be similar to those described previously, and the optical engine 500 may be similar to other optical engines described previously, except for the inclusion of both a photodetector die 50 and a modulator die 70. For example, the optical engine 500 includes a lens 38A, a grating coupler 16A, waveguides 15A/26A/42A, and an electronic die 30A that are associated with the modulator die 70, and includes a lens 38B, a grating coupler 16B, waveguides 15B/26B/42B, and an electronic die 30B that are associated with the photodetector die 50. The electronic die 30A is electrically connected to the modulator die 70, and the electronic die 30B is electrically connected to the photodetector die 50. The optical engine 500 may be formed using materials or techniques similar to those described previously. For example, the photodetector die 50 and the modulator die 70 may be bonded to the PIC 40 using direct bonding techniques. In some embodiments, waveguides may be coupled to the photodetector die 50 and the modulator die 70 to allow optical communication between the photodetector die 50 and the modulator die 70. In some embodiments, multiplexors or demultiplexors (not illustrated) may be incorporated into the optical engine 500 to facilitate optical communication within the optical engine 500. The arrows 101 represent possible paths of optical signals or optical power that enters or exits the optical engine 500. The optical engine 500 shown in FIG. 20 is an illustrative example, and other configurations or arrangements are possible.

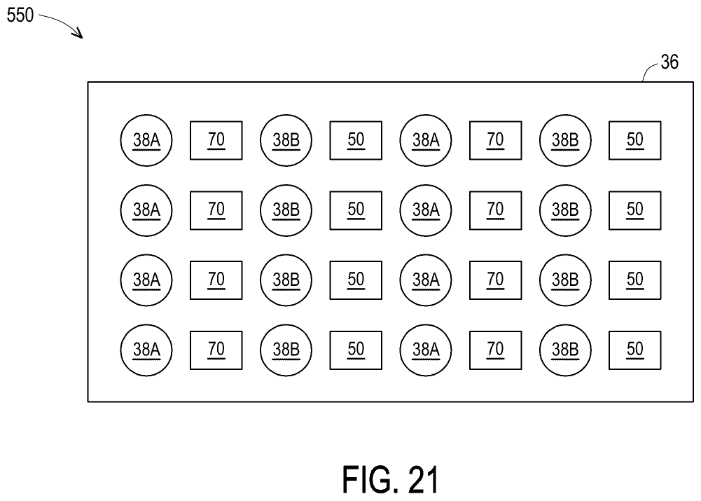

FIG. 21 illustrates a simplified top-down view of an optical engine 550, in accordance with some embodiments. The optical engine 550 may be similar to the optical engine 500, except that the optical engine 550 includes multiple photodetector dies 50 and multiple modulator dies 70. In the optical engine 550, each photodetector die 50 has an associated lens 38B, and each modulator die 70 has an associated lens 38A. The lenses 38A-B, photodetector dies 50, and modulator dies 70 may be arranged in an array or in any suitable arrangement. The photodetector dies 50 and modulator dies 70 may each have an associated electronic die 30 (not illustrated), in some cases. The photodetector dies 50 and modulator dies 70 may be optically connected by waveguides (not illustrated), in some cases. In this manner, an optical engine may facilitate high-speed optical communication through the use of multiple photodetector dies 50 and multiple modulator dies 70. The optical engine 550 shown in FIG. 21 is an illustrative example, and other configurations, arrangements, or numbers of features are possible.

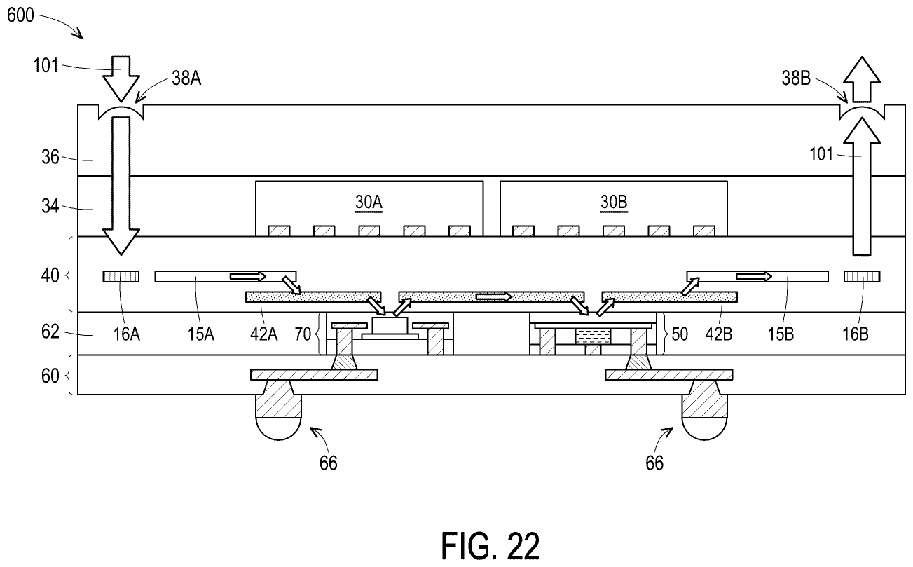

FIG. 22 illustrates an optical engine 600, in accordance with some embodiments. The optical engine 600 is similar to the optical engine 350 of FIG. 17, except that the optical engine 600 includes both a modulator die 70 and a photodetector die 50. The optical engine 600 may be similar to the optical engine 500 of FIG. 20, in some cases. For clarity, some features may not be illustrated in FIG. 22. The optical engine 600 may be formed using materials or techniques similar to those described previously. For example, the photodetector die 50 and the modulator die 70 may be bonded to the PIC 40 using direct bonding techniques. In some embodiments, a waveguide 42C may be coupled to the photodetector die 50 and the modulator die 70 that allows optical communication between the photodetector die 50 and the modulator die 70. In some embodiments, multiplexors or demultiplexors (not illustrated) may be incorporated into the optical engine 600 to facilitate optical communication within the optical engine 600. FIG. 22 illustrates a simplified optical path diagram (represented by arrows 101), in accordance with some embodiments. The arrows 101 represent a possible path of optical signals or optical power that enters the optical engine 600, are modulated by the modulator die 70 and/or detected by the photodetector die 50, and then are transmitted out of the optical engine 600. In some cases, optical signals may be transmitted in either direction along an optical path, and not just in the direction indicated by the arrows 101. The optical engine 600 shown in FIG. 22 is an illustrative example, and other configurations or arrangements are possible.

The optical signals may be transmitted to the optical engine 600 from an optical fiber or the like (not separately illustrated). The optical signals are transmitted through the lens 38A, the support 36, and the dielectric material 34 to the grating coupler 16A within the PIC 40. The grating coupler 16A receives the optical signals and couples the optical signals into the silicon waveguide 15A. The optical signals are then evanescently coupled from the silicon waveguide 15A into the waveguide 42A. The optical signals are then evanescently coupled from the waveguide 42A into the modulator die 70. The modulator die 70 receives electrical signals and modulates the optical signals based on the electrical signals. The modulated optical signals may be evanescently coupled from the modulator die 70 into the waveguide 42C. The optical signals are then evanescently coupled from the waveguide 42C into the photodetector die 50. The photodetector die 50 detects the optical signals and generates corresponding electrical signals. After detection by the photodetector die 50, optical signals may be evanescently coupled into the waveguide 42B. The optical signals may then be evanescently coupled into the waveguide 15B and then into the grating coupler 16B. The grating coupler 16B directs the optical signals upward through the dielectric material 34 and support 36 to the lens 38B. The optical signals may then be coupled by the lens 38B to an external optical component, such as an optical fiber or the like. In this manner, the techniques described herein allows for the incorporation of a high-speed modulator and a high-speed photodetector into an optical engine, thus enabling high-bandwidth optical communication.

Embodiments of the present disclosure have some advantageous features. Forming an optical engine by directly bonding a photonic die to a photonic integrated circuit (PIC) can allow for the use of materials in photonic components that may otherwise be difficult or costly to form, for example, by processing the materials during formation of the optical engine or by bonding wafer-scale structures to the PIC. The photonic components may include, for example, high-speed photodetectors or modulators. As non-limiting examples, photodetectors using III-V materials may be formed in a photodetector die, and modulators using thin film lithium niobate (TFLN) may be formed in a modulator die. In this manner, high data rates, such as data rates greater than about 400 Gbps, may be achieved in an optical engine. Additionally, directly bonding the photonic dies can allow for thinner photonic dies, which can enable more efficient optical coupling to the PIC and/or thinner optical engines. The photonic dies can be coupled to waveguides within the PIC to allow for high-speed optical communication within an optical engine. In this manner, photonic dies can be heterogeneously integrated into optical engines, and optical engines can be formed at a reduced cost and having a higher data rate.

In an embodiment of the present disclosure, a method includes forming a photonic integrated circuit including: a first waveguide; a second waveguide over the first waveguide, wherein the second waveguide is optically coupled to the first waveguide; a first external coupler that is optically coupled to the second waveguide; and a first interconnect structure; attaching an electronic die to a first side of the photonic integrated circuit; direct bonding a first photonic die to a second side of the photonic integrated circuit, wherein the first photonic die is optically coupled to the first waveguide after the direct bonding; and forming a second interconnect structure over the first photonic die and the photonic integrated circuit. In an embodiment, the photonic die includes a lithium niobate modulator. In an embodiment, the photonic die includes a III-V photodetector. In an embodiment, the direct bonding includes a dielectric-to-dielectric bonding process. In an embodiment, the method includes forming a lens over the first side of the photonic integrated circuit, wherein the lens is optically coupled to the first external coupler. In an embodiment, the first external coupler is a grating coupler. In an embodiment, the first external coupler is an edge coupler. In an embodiment, the method includes direct bonding a second photonic die to the second side of the photonic integrated circuit, wherein the second photonic die is optically coupled to the first waveguide after the direct bonding.

In an embodiment of the present disclosure, a method includes patterning a first photonic layer to form a first waveguide, wherein the first photonic layer is on a first side of a first insulating layer; forming a first interconnect structure over the first waveguide; bonding a first electronic die to the first interconnect structure; patterning a second photonic layer to form a second waveguide, wherein the second photonic layer is on a second side of a first insulating layer, wherein the second waveguide overlaps the first waveguide; depositing a second insulating layer over the second waveguide; bonding a photonic die to the second insulating layer, wherein the photonic die overlaps the second waveguide; and forming a second interconnect structure over the photonic die and over the second insulating layer, wherein the second interconnect structure is electrically connected to the photonic die and to the first interconnect structure. In an embodiment, the method includes depositing a second insulating layer over the first waveguide; and forming a third waveguide on the second insulating layer, wherein the third waveguide overlaps the first waveguide. In an embodiment, the method includes forming a dual grating coupler adjacent the third waveguide that is optically coupled to the third waveguide. In an embodiment, the first photonic layer and the second photonic layer are different materials. In an embodiment, bonding a photonic die to the second insulating layer uses a fusion bonding process. In an embodiment, the method includes patterning the second photonic layer to form a fourth waveguide, wherein the photonic die overlaps the fourth waveguide. In an embodiment, the photonic die includes a fifth waveguide.

In an embodiment of the present disclosure, an optical device includes a first interconnect structure; a photonic device on the first interconnect structure, wherein the photonic device physically and electrically contacts the first interconnect structure; first waveguides over the photonic device, wherein the first waveguides are coupled to the photonic device; second waveguides over the first waveguides, wherein the second waveguides are coupled to the first waveguides; grating couplers adjacent to the second waveguides, wherein the grating couplers are optically coupled to the second waveguides; a second interconnect structure over the second waveguides; and an electronic die bonded to the second interconnect structure. In an embodiment, the photonic device includes a thin film lithium niobate modulator. In an embodiment, at least one of the first waveguides is a silicon nitride waveguide. In an embodiment, at least one of the second waveguides is a silicon waveguide. In an embodiment, the optical device includes a conductive via extending from the first interconnect structure to the second interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a photonic integrated circuit comprising:
a first waveguide;
a second waveguide over the first waveguide, wherein the second waveguide is optically coupled to the first waveguide;
a first external coupler that is optically coupled to the second waveguide; and
a first interconnect structure;
attaching an electronic die to a first side of the photonic integrated circuit;
direct bonding a first photonic die to a second side of the photonic integrated circuit, wherein the first photonic die is optically coupled to the first waveguide after the direct bonding; and
forming a second interconnect structure over the first photonic die and the photonic integrated circuit.

2. The method of claim 1, wherein the photonic die comprises a lithium niobate modulator.

3. The method of claim 1, wherein the photonic die comprises a III-V photodetector.

4. The method of claim 1, wherein the direct bonding comprises a dielectric-to-dielectric bonding process.

5. The method of claim 1 further comprising forming a lens over the first side of the photonic integrated circuit, wherein the lens is optically coupled to the first external coupler.

6. The method of claim 1, wherein the first external coupler is a grating coupler.

7. The method of claim 1, wherein the first external coupler is an edge coupler.

8. The method of claim 1 further comprising direct bonding a second photonic die to the second side of the photonic integrated circuit, wherein the second photonic die is optically coupled to the first waveguide after the direct bonding.

9. A method comprising:
patterning a first photonic layer to form a first waveguide, wherein the first photonic layer is on a first side of a first insulating layer;
forming a first interconnect structure over the first waveguide;
bonding a first electronic die to the first interconnect structure;
patterning a second photonic layer to form a second waveguide, wherein the second photonic layer is on a second side of a first insulating layer, wherein the second waveguide overlaps the first waveguide;
depositing a second insulating layer over the second waveguide;
bonding a photonic die to the second insulating layer, wherein the photonic die overlaps the second waveguide; and
forming a second interconnect structure over the photonic die and over the second insulating layer, wherein the second interconnect structure is electrically connected to the photonic die and to the first interconnect structure.

10. The method of claim 9 further comprising:
depositing a second insulating layer over the first waveguide; and
forming a third waveguide on the second insulating layer, wherein the third waveguide overlaps the first waveguide.

11. The method of claim 10, further comprising forming a dual grating coupler adjacent the third waveguide that is optically coupled to the third waveguide.

12. The method of claim 9, the first photonic layer and the second photonic layer are different materials.

13. The method of claim 9, wherein bonding a photonic die to the second insulating layer uses a fusion bonding process.

14. The method of claim 9 further comprising patterning the second photonic layer to form a fourth waveguide, wherein the photonic die overlaps the fourth waveguide.

15. The method of claim 9, wherein the photonic die comprises a fifth waveguide.

16. An optical device comprising:
a first interconnect structure;
a photonic device on the first interconnect structure, wherein the photonic device physically and electrically contacts the first interconnect structure;
a plurality of first waveguides over the photonic device, wherein the plurality of first waveguides are coupled to the photonic device;
a plurality of second waveguides over the plurality of first waveguides, wherein the plurality of second waveguides are coupled to the plurality of first waveguides;
a plurality of grating couplers adjacent to the plurality of second waveguides, wherein the plurality of grating couplers are optically coupled to the plurality of second waveguides;
a second interconnect structure over the plurality of second waveguides; and
an electronic die bonded to the second interconnect structure.

17. The optical device of claim 16, wherein the photonic device comprises a thin film lithium niobate modulator.

18. The optical device of claim 16, wherein at least one of the plurality of first waveguides is a silicon nitride waveguide.

19. The optical device of claim 16, wherein at least one of the plurality of second waveguides is a silicon waveguide.

20. The optical device of claim 16 further comprising a conductive via extending from the first interconnect structure to the second interconnect structure.
